(19) United States
(12) Patent Application Publication
(10) Pub. No.: US 2007/0145434 A1
(43) Pub. Date: Jun. 28, 2007

(54) SEMICONDUCTOR DEVICE

(76) Inventor: Jung Ho Kim, Seoul (KR)

Correspondence Address: SHERR & NOURSE, PLLC, 620 HERNDON PARKWAY, SUITE 200, HERNDON, VA, 20170, US

(21) Appl. No.: 11/616,283

(22) Filed: Dec. 26, 2006

(30) Foreign Application Priority Data
Dec. 28, 2005 (KR) 10-2005-0131624

(51) Int. Cl. H01L 29/76

(52) U.S. Cl. 257/288

(57) ABSTRACT

Embodiments relate to a method for manufacturing a semiconductor substrate. According to embodiments, a gate oxide layer may be formed on a semiconductor substrate. Also, a well region may be formed in the semiconductor substrate including the gate oxide layer. Then, after forming a gate electrode on the semiconductor substrate, a liner layer may be formed on the semiconductor substrate. Next, the semiconductor substrate including the liner layer may be annealed to form an annealed liner layer. Finally, an interlayer insulation layer may be formed on the annealed liner layer.

The present application claims priority under 35 U.S.C. 119 and 35 U.S.C. 365 to Korean Patent Application No. 10-2005-0131624 (filed on Dec. 28, 2005), which is hereby incorporated by reference in its entirety.

### BACKGROUND

A high voltage semiconductor device may be used when a high voltage is input from an external system or when a high voltage or a high current output is required, for example for driving a motor.

A high voltage semiconductor device may include both a high voltage driving part and a low voltage driving part on a single chip. In the high voltage semiconductor, a low voltage may be applied to a gate electrode and a high voltage may be applied to a drain electrode to simultaneously operate a low voltage driving part and a high voltage driving part.

A through gate-oxide implantation (TGI) process may be performed during a manufacturing process of a high voltage semiconductor device to form the low and high voltage driving parts on a chip while maintaining characteristics of the low and high voltage driving parts.

The TGI process may be an ion implantation process for forming a well region in a semiconductor substrate on which a high voltage gate oxide layer may be deposited.

FIGS. 1 and 2 are example cross-sectional diagrams illustrating a related art method for manufacturing a semiconductor device. A high voltage device region may be defined in a semiconductor substrate is depicted in FIGS. 1 and 2.

Referring to FIG. 1, device isolation layer 12, which may define a device isolation region, may be formed in semiconductor substrate 10. Semiconductor substrate 10 may include high and low voltage device regions.

High voltage gate oxide layer 14 may be formed in semiconductor substrate 10, and a low voltage gate oxide layer (not shown) may be formed in a low voltage device region of the substrate.

Photoresist pattern 15 may be formed on semiconductor substrate 10 including high voltage gate oxide layer 14. Ion implantation may be performed to form well region 16 using photoresist pattern 15 as a mask.

Referring to FIG. 2, photoresist pattern 15 may be removed. Gate electrode 18 may be formed on semiconductor substrate 10 including well region 16. Preferential metal deposition (PMD) layer based liner layer 20 may be formed on a surface of semiconductor substrate 10 including gate electrode 18.

Interlayer insulation layer 22 may be formed of one of a boro-phosphosilicate glass (BPSG), a phosphosilicate glass (PSG), and an undoped silicate glass (USG) based material on a surface (for example, an entire surface) of a resultant structure including liner layer 20.

During an ion implantation process for forming well region 16, impurity ions may also be implanted in exposed high voltage gate oxide layer 14. Thus a portion of gate oxide layer 14 disposed on the well region may change into ion implanted oxide layer 14a.

Trap sites may be generated in ion implanted oxide layer 14a. Substances such as H₂O and B that may be distributed in interlayer insulation layer 22 may move into the trap sites in ion implanted oxide layer 14a.

This may lead to an increase in an electric current leakage in a threshold voltage region of a high voltage device, which may increase power consumption, and may deteriorate a device.

### SUMMARY

Embodiments relate to a semiconductor device, and to a high voltage semiconductor device.

Embodiments relate to a method of manufacturing a semiconductor device that may be capable of preventing an electric current leakage in a high voltage device.

In embodiments, a semiconductor device may include a semiconductor substrate having a device isolation layer, a well region formed in the semiconductor substrate, a gate oxide layer formed on the semiconductor substrate, a gate electrode formed on the gate oxide layer, an annealed liner layer formed on the gate oxide layer and the gate electrode, and an interlayer insulation layer formed on the annealed liner layer.

In embodiments, a method for manufacturing a semiconductor device may include forming a gate oxide layer on a semiconductor substrate, forming a well region in the semiconductor substrate having the gate oxide layer, forming a gate electrode on the semiconductor substrate, forming a liner layer on the semiconductor substrate, annealing the semiconductor substrate including the liner layer to form an annealed liner layer, and forming an interlayer insulation layer on the annealed liner layer.

### BRIEF DESCRIPTION OF THE DRAWINGS

FIGS. 1 and 2 are example cross-sectional diagrams illustrating a related art method for manufacturing a semiconductor device;

FIGS. 3 to 6 are example cross-sectional diagrams illustrating a method for manufacturing a semiconductor device according to embodiments.

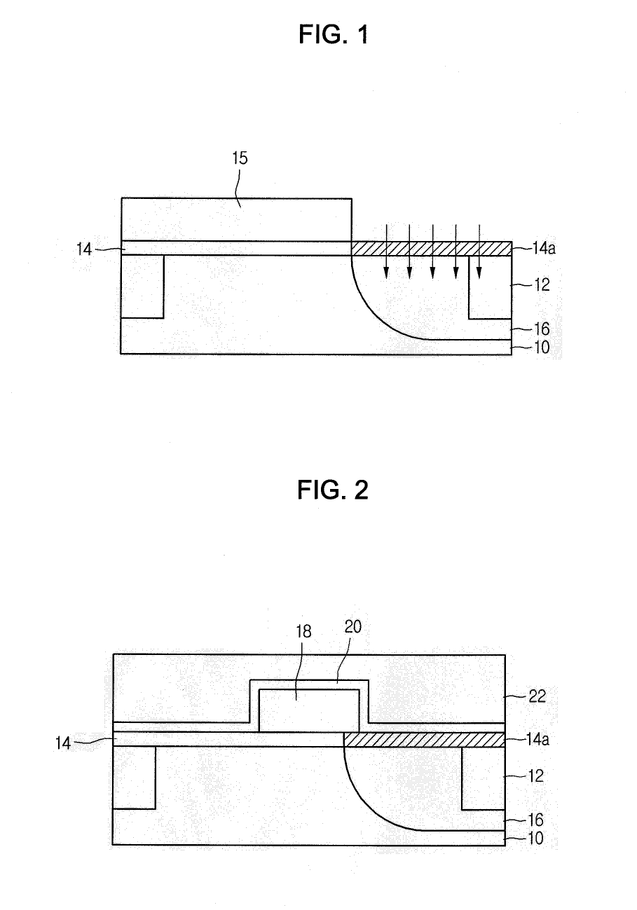

### DETAILED DESCRIPTION OF EMBODIMENTS

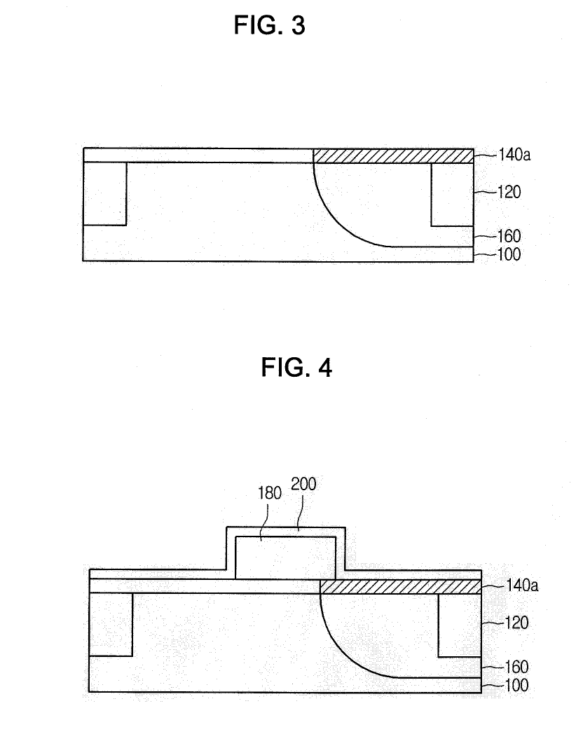

A high voltage device region defined in a semiconductor substrate may be depicted in FIGS. 3 to 6.

Referring to FIG. 3, device isolation layer 120 may be formed in semiconductor substrate 100, in which a high and a low voltage device region may be defined.

A pad layer may be formed on semiconductor substrate 100, and a photoresist pattern, which may define a device isolation region, may be formed on the pad layer. Semiconductor substrate 100 and the pad layer may be etched to form a trench using the photoresist pattern.

A trench filling insulation layer may be formed only inside the trench to form device isolation layer 120.

High voltage gate oxide layer 140 may be formed in the high voltage device region of semiconductor substrate 100. Similarly, although not shown, a low voltage gate oxide layer may be formed in the low voltage device region.

A photoresist pattern may be formed on semiconductor substrate 100 including the high voltage gate oxide layer 140. An ion implantation process may then be performed on semiconductor substrate 100 to form well region 160 using the photoresist pattern as a mask. In embodiments, well region 160 may be formed to surround device isolation region 120.

According to embodiments, during the ion implantation process for forming well region 160, a portion of the ions may be implanted in high voltage gate oxide layer 140, which may form ion implanted gate oxide layer 140a.

Referring to FIG. 4, a conductive layer, such as a polysilicon layer, may be deposited and patterned on a resultant structure including well region 160, and may form gate electrode 180.

One of a PMD layer based material, a middle temperature oxide (MTO) based material, and a high temperature oxide (HTO) based material may be deposited on semiconductor substrate 100 including gate electrode 180 to form liner layer 200. In embodiments, liner layer 200 may be also formed on a sidewall of gate electrode 180.

Liner layer 200 may be formed to electrically isolate gate electrode 180 from a metal line, that may be formed subsequently.

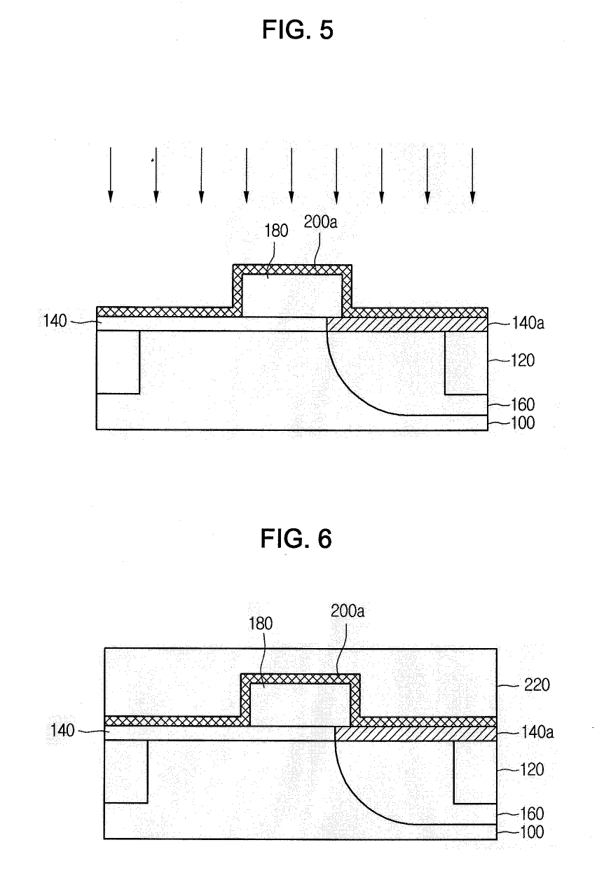

Referring to FIG. 5, an annealing of a resultant structure, including liner layer 200, may be performed to form annealed liner layer 200a.

The annealing may be performed at a temperature range of approximately 600˜1000° C. under N₂ or H₂ atmosphere.

The annealed liner layer may prevent movement of H₂O and B more easily than a non-annealed liner layer may.

Referring to FIG. 6, an interlayer insulation layer may be formed of one of a BPSG, a PSG, and a USG based material on a resultant structure, including annealed liner layer 200a.

Annealed liner layer 220a may prevent the movement of a substance such as H₂O and B in interlayer insulation layer 220 to the trap sites generated in ion implanted gate oxide layer 140a.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device comprising:
a semiconductor substrate including a device isolation layer;
a well region formed in the semiconductor substrate;
a gate oxide layer formed over the semiconductor substrate;
a gate electrode formed over the gate oxide layer; and
an annealed liner layer formed over the gate oxide layer and the gate electrode.

2. The device of claim 1, further comprising an interlayer insulation layer formed over the annealed liner layer.

3. The device of claim 1, wherein the annealed liner layer is formed on a sidewall of the gate electrode.

4. The device of claim 1, wherein the semiconductor substrate comprises a high and a low voltage device region, and the annealed liner layer is formed in the high voltage device region of the semiconductor substrate.

5. The device of claim 1, wherein the annealed liner layer is formed by annealing one of a preferential metal deposition layer based layer, a middle temperature oxide based layer, and a high temperature oxide based layer.

6. The device of claim 1, were the gate oxide layer comprises an ion implanted oxide layer formed over the well region and an oxide layer formed over a non-well region.

7. A method comprising:
forming a gate oxide layer over a semiconductor substrate;
forming a well region in the semiconductor substrate including the gate oxide layer;
forming a gate electrode over the semiconductor substrate;
forming a liner layer over the semiconductor substrate; and
annealing the semiconductor substrate including the liner layer to form an annealed liner layer.

8. The method of claim 7, further comprising forming an interlayer insulation layer on the annealed liner layer.

9. The method of claim 7, where the gate oxide layer comprises an ion implanted oxide layer formed over the well region in the semiconductor substrate, and an oxide layer formed over remaining portions of the semiconductor substrate.

10. The method of claim 7, wherein the gate electrode is formed over a portion of the ion implanted oxide layer and a portion of the oxide layer.

11. The method of claim 7, wherein the annealing is performed at a temperature range of 600˜1000° C. under a N₂ or H₂ atmosphere.

12. The method of claim 7, wherein forming the liner layer comprises depositing at least one of a preferential metal deposition layer based material, a middle temperature oxide based material, and a high temperature oxide based material.

13. The method of claim 7, further comprising forming a device isolation layer in the semiconductor substrate to divide a high voltage device region from a low voltage device region before the forming of the gate oxide layer.

14. The method of claim 13, wherein the liner layer is formed in the high voltage device region of the semiconductor substrate.

15. The method of claim 7, wherein the interlayer insulation layer comprises at least one of a boro-phosphosilicate glass, a phosphosilicate glass and an undoped silicate glass.

16. A device, comprising:
a semiconductor substrate having a well region formed therein;
an ion implanted oxide layer over at least a portion of the well region; and
an annealed linear layer over at least a portion of the ion implanted oxide layer.

17. The device of claim 16, further comprising:
a gate electrode formed over a portion of the ion implanted oxide layer and a portion of an oxide layer;
in interlayer insulation layer formed over the annealed linear layer, where the annealed linear layer is formed over the gate electrode.

18. The device of claim 17, wherein the annealed linear layer is formed on a side wall of the to electric.

19. The device of claim 17, wherein the oxide layer and the ion implanted oxide layer form a single gate oxide layer over the semiconductor substrate.

20. The device of claim 17, further comprising a device isolation layer configured to divide the semiconductor substrate into a high voltage device region and a low voltage device region, wherein the liner layer is formed in the high voltage device region.
